(19) United States
(12) Patent Application Publication
(10) Pub. No.: US 2023/0400538 A1
(43) Pub. Date: Dec. 14, 2023

(54) USE OF LACTIC ACID IN HYPERPOLARIZATION FOR MAGNETIC RESONANCE APPLICATIONS

(71) Applicant: GE PRECISION HEALTHCARE LLC, Wauwatosa, WI (US)

(72) Inventors: Daniel M. Ruscitto, Niskayuna, NY (US); Rui Chen, Clifton Park, NY (US); Albert Po Fu Chen, Toronto (CA); Gregory D. Goddard, Ballston Spa, NY (US); Chunxin Zhang, Clifton Park, NY (US)

(21) Appl. No.: 17/837,794

(22) Filed: Jun. 10, 2022

(51) Int. Cl. G01R 33/28

(52) U.S. Cl. CPC G01R 33/282; G01R 33/31

(57) ABSTRACT

A composition is provided. The composition includes a magnetic resonance (MR) probe and a glassification agent. The glassification agent includes lactic acid.

### STATEMENT REGARDING FEDERALLY SPONSORED RESEARCH & DEVELOPMENT

This invention was made with government support under grant number R01CA214554 awarded by the National Institutes of Health. The government has certain rights in the invention.

### BACKGROUND

Magnetic resonance (MR) applications, including imaging and spectroscopic applications, have proven useful in diagnosis of many diseases. MR applications provide detailed images of soft tissues, e.g., abnormal tissues such as tumors and other structures, and characterization of the chemical composition of tissues such as small molecules involved in metabolic processes that may be altered in a diseased state, which cannot be readily assessed by other modalities, such as computed tomography (CT). MR is advantageous also because MR applications operate without exposing patients to ionizing radiation, compared to CT and positron emission tomography (PET).

Known compositions and preparation methods of MR probes are disadvantaged in some aspects and improvements are desired.

### BRIEF DESCRIPTION

In one aspect, a composition is provided. The composition includes a magnetic resonance (MR) probe and a glassification agent. The glassification agent includes lactic acid.

In another aspect, a method of preparing a hyperpolarized magnetic resonance (MR) probe material is provided. The method includes preparing a composition including an MR probe, an electron paramagnetic agent (EPA), and a glassification agent. The glassification agent includes lactic acid. The method further includes obtaining a hyperpolarized amorphous solid MR probe material by carrying out polarization on the composition.

In yet another aspect, a method of preparing a hyperpolarized magnetic resonance (MR) probe is provided. The method includes preparing a composition including an MR probe, an electron paramagnetic agent (EPA), and a glassification agent. The glassification agent includes lactic acid. The method further includes carrying out polarization on the composition to obtain a hyperpolarized amorphous solid MR probe material. The method also includes liquefying the hyperpolarized amorphous solid MR probe material by dissolving the hyperpolarized amorphous solid MR probe material to obtain a hyperpolarized liquid MR probe solution.

### DRAWINGS

Non-limiting and non-exhaustive embodiments are described with reference to the following Figures, wherein like reference numerals refer to like parts throughout the various drawings unless otherwise specified.

FIG. 1A is a block diagram of an exemplary MR workflow.

FIG. 1B is a flowchart of an exemplary method for preparing a hyperpolarized amorphous solid MR probe material.

FIG. 1C is a flowchart of an exemplary method for preparing a hyperpolarized liquid MR probe solution.

FIG. 2 is a heat flow plot of differential scanning calorimetry (DSC) studies on lactic acid (LA):urea mixtures.

FIG. 3A is an exemplary solid phase buildup curve from 4.2:1 [1-¹³C] LA/[¹³C, ¹⁵N] urea mixture with electron paramagnetic agent (EPA).

FIG. 3B is an exemplary free induction decay (FID) from 4.2:1 [1-¹³C] LA/[¹³C, ¹⁵N] urea mixture with EPA.

FIG. 3C is an exemplary spectrum from 4.2:1 [1-¹³C] LA/[¹³C, ¹⁵N] urea mixture with EPA.

FIG. 4A is an exponential fit of dissolved [1-¹³C] lactate, T1=49 s.

FIG. 4B is an exponential fit of dissolved [¹³C,¹⁵N] urea, T1=45 s.

FIG. 5 is a nuclear magnetic resonance (NMR) spectrum of the first measurement of hyperpolarized LA/urea dissolution product 91s after dissolution started.

FIG. 6 is a NMR spectrum of the first measurement of LA only dissolution product 108s after dissolution started.

FIG. 7A shows absorbance spectra for LA and EPA solutions using an UV-VIS spectrometer through quartz 1-cm pathlength cuvettes.

FIG. 7B shows absorbance spectra for LA and EPA solutions using an UV-VIS spectrometer through disposable 1-cm pathlength cuvettes.

FIG. 8A shows exemplary ¹³C NMR spectra of LA in water.

FIG. 8B shows chemical structures of LA and related compounds.

FIG. 9 shows exemplary ¹³C NMR spectra of LA in water with EPA added.

FIG. 10 shows an exemplary comparison of ¹³C NMR spectra for LA in water with EPA versus without EPA.

FIG. 11 shows exemplary ¹³C NMR spectra of LA and urea mixture.

FIG. 12 shows exemplary ¹³C NMR spectra of LA and urea mixture with EPA added.

FIG. 13 shows an exemplary comparison of ¹³C NMR spectra for LA and urea mixture with EPA versus without EPA.

FIG. 14 shows an exemplary summary comparison of ¹³C NMR spectra for LA in water with or without EPA versus LA and urea mixture with or without EPA.

### DETAILED DESCRIPTION

The present disclosure includes hyperpolarized MR probe compositions and methods for preparing hyperpolarized MR probe compositions. The compositions include lactic acid as a glassification agent. Method aspects will be in part apparent and in part explicitly discussed in the following description.

In MR applications, a subject is placed in a magnet. As used herein, a subject is a human, an animal, or a phantom, or part of a human, an animal, or a phantom. When the subject is in the magnetic field generated by the magnet, magnetic moments of nuclei, such as protons, attempt to align with the magnetic field but precess about the magnetic field in a random order at the nuclei's Larmor frequency. The magnetic field of the magnet is referred to as B0 and extends in the longitudinal or z direction. In acquiring an MRI image, a magnetic field (referred to as an excitation field B1), which is in the x-y plane and near the Larmor frequency, is generated by a radio-frequency (RF) coil and may be used to rotate, or “tip,” the net magnetic moment Mz of the nuclei from the z direction to the transverse or x-y plane. A signal, which is referred to as an MR signal, is emitted by the nuclei, after the excitation signal B1 is terminated. To use the MR signals to generate an image of a subject, magnetic field gradient pulses (Gx, Gy, and Gz) are used. The gradient pulses are used to scan through the k-space, the space of spatial frequencies or inverse of distances. A Fourier relationship exists between the acquired MR signals and an image of the subject, and therefore an image of the subject is derived by reconstructing the MR signals. In MR spectroscopy, scanning through the k-space with imaging gradients is not performed and the MR signals of selected voxels are used to generate spectra.

Typically, MR imaging (MRI) and spectroscopy (MRS) detect MR signals emitted from nuclei of hydrogen protons (¹H) because the abundance of water in a subject. Carbon MR imaging or spectroscopy is of significant interest because carbon is the backbone of organic molecules and enables analysis of relevant biochemical pathways for disease monitoring and treatment in the human body as well as in non-human animal subjects. Carbon 12 (¹²C), however, is not detectable by MR due to the lack of spin in ¹²C. Although carbon 13 (¹³C) is detectable by MR, several factors limit ¹³C MRI/MRS. The gyromagnetic ratio of ¹³C is only approximately ¼ of ¹H, greatly reducing magnitude of MR signals. Naturally occurring ¹³C is only 1.1% of carbon. Further, the centration of carbon in a subject is much lower than ¹H. For example, a human body has 60-70% of water, in which the concentration of ¹H is approximately 110 M, while the most concentrated metabolites are present in the mM ranges. As a result, MRI/MRS of endogenous ¹³C is impossible at reasonable imaging times.

Hyperpolarization of ¹³C MR probes significantly increases detectable ¹³C MR signals, for example, on the order of 10⁴, thereby allowing in vivo ¹³C MRI/MRS within reasonable time. Hyperpolarized ¹³C MR probes are not radioactive. As a result, hyperpolarized ¹³C MR probes are safe to be used in vivo, advantageous over contrast agents used in positron emission tomography (PET) for studying metabolites.

Hyperpolarized ¹³C MR probes are also advantageous over other contrast agents for MR applications. Paramagnetic metal chelate complexes such as gadolinium chelates or superparamagnetic iron oxide particles are typical contrast agents used in MR applications. Typical MR contrast agents lack specificity, compared to hyperpolarized ¹³C MR probes. Further, toxic metal ions in paramagnetic metal chelate complexes may be released in the body after administration.

In the exemplary embodiment, the MR probe is a carbon and/or nitrogen-containing, biologically relevant, organic molecule that will enable metabolic characterization of a metabolic process. As used herein, a biologically relevant MR probe is a compound that is relevant to biological organs or tissues, such as humans, animals, plants and/or environmental health, and may be used to detect and/or indicate characteristics and functions in the biological organs or tissues. A biologically relevant MR probe may be an endogenous, naturally-occurring compound in the body, or a non-endogenous compound.

T1 is the time constant in the process by which the net magnetization returns to the initial value Mz, such that the MR signal of a hyperpolarized MR probe decays due to relaxation time T1 upon administration to a subject. Accordingly, the T1 value of an MR probe, in biological fluids such as blood, should be long enough to enable the probe molecule to be distributed to a target site in the subject and scanned while in the highly hyperpolarized state. Biologically relevant MR probes with suitable T1 relaxation times include carbonyl compounds because carbon atoms that do not have directly-attached protons, such as many carbonyl group carbons, generally have relatively long T1 relaxation times in the order of tens of seconds. For example, pyruvate has a T1 of 65 seconds at 3T. Biologically relevant non-carbonyl compounds having suitable T1 relaxation times are also contemplated herein as MR probes, such as cyclic carbohydrates and quaternary ammonium compounds.

In the exemplary embodiment, the MR probe is a carbonyl compound. The carbonyl compound may be selected from a carboxylic acid or urea. The carboxylic acid may be selected from maleic acid, acetic acid, fumaric acid, pyruvic acid, malonic acid. Succinic acid, oxaloacetic acid, lactic acid, ketoglutaric acid, nicotinic acid, alanine, glycine, cysteine, proline, tyrosine, sarcosine, gamma-aminobutyric acid (GABA), and homocysteine. Alternative carbonyl compounds with carbonyl carbons having either one or no directly-attached protons are also contemplated herein, for example aldehydes, nitrogenous carbonyls, ketones, amides, imines, and esters.

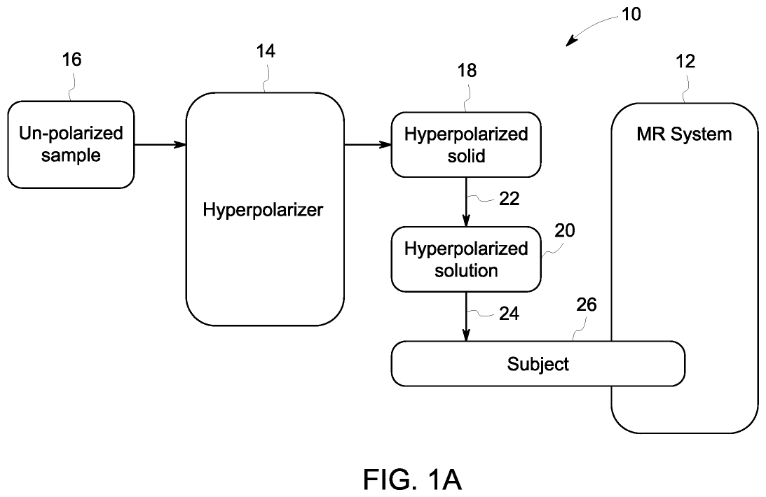

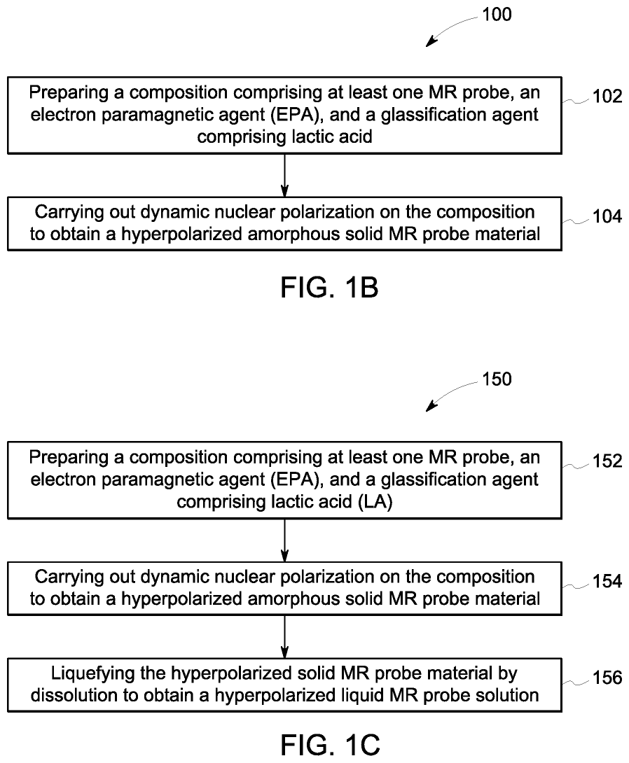

FIG. 1A illustrates a schematic block diagram of an exemplary MR workflow 10. MR system 12 is used to obtain images or for spectroscopy applications of a subject 26. Exemplary MR workflow 10 also includes a hyperpolarizer 14, which polarizes a MR probe molecule present in unpolarized sample 16 into hyperpolarized solid 18, as described below. Hyperpolarized solid 18 is converted to hyperpolarized sample 20 via dissolution 22. Prior to injection into subject 26, a filtration and/or neutralization 24 is performed on hyperpolarized sample 20 in order to provide a safe injectable MR probe solution. Hyperpolarized nuclear spins in the hyperpolarized sample 20 relax to thermal equilibrium with a time constant T1 of typically 40-80 seconds at 1.5-3 T. To take advantage of a hyperpolarized MR probe for acquiring significantly increased MR signals, rapid transfer of the hyperpolarized MR probe solution is needed for injecting into the subject. Upon injection of the hyperpolarized liquid MR probe, subject 26 is scanned using MR system 12.

In the exemplary embodiment, hyperpolarization is achieved by dissolution dynamic nuclear polarization (DNP), which involves making a solution with highly polarized ¹³C and/or ¹⁵N nuclear spins on a carbon and/or nitrogen-containing molecule. An initial solution (unpolarized sample 16 in FIG. 1A) includes at least the MR probe and a free electron agent such as an electron paramagnetic agent (EPA), and a glassification agent including LA. Unpaired spins in EPA are transferred to MR probes during the DNP process.

In the exemplary embodiment, the EPA is a trityl radical. Oxygen-based, sulphur-based or carbon-based trityl radicals as EPA for hyperpolarization of MR probes via DNP results in high polarization levels for MR probes. In the exemplary embodiment, the EPA includes at least one of an oxygen-based trityl radical, a sulphur-based trityl radical, or a carbon-based trityl radical. Alternative EPA compounds are also contemplated herein.

Within the hyperpolarizer 14, the initial solution is cooled to approximately 1K within a magnetic field typically of 3.0-7.0 T, and solidified. The solid is subsequently irradiated with microwaves to transfer the high polarization of the free electrons in EPA to the MR probe's ¹³C and/or ¹⁵N nuclei, thus imparting the enhanced polarization to the MR probe.

In order for the DNP process to be effective, EPA should be in close proximity with MR probes to be polarized. The interaction between EPA and ¹³C MR probes is greatly increased in an amorphous solid compared to a crystalized solid. To facilitate the transfer of high levels of polarization in EPA to ¹³C MR probes, an amorphous solid should be formed in the hyperpolarizer 14. The process of forming an amorphous solid may be referred to as glassification. A glassification agent is often needed in a glassification process for the mixture of EPA and ¹³C MR probes to form an amorphous solid, instead of a crystalized solid. Water is a poor glassification agent because water crystallizes in a solid state.

Dissolution 22 of the now-hyperpolarized amorphous solid MR probe material (hyperpolarized solid 18 in FIG. 1A) is performed to generate a final solution (hyperpolarized liquid 20 in FIG. 1A). After dissolution 22, the EPA is removed. The level of EPA in the final solution should be below a level, such as below 3 μM to 5 μM before being injected into a subject. Besides being used as a glassification agent, LA also facilitates the removal of EPA because EPA becomes insoluble in an acidic environment. The size of formed insoluble particles varies with acid type and acid concentration. The filtered solution is subsequently neutralized to physiological pH (filtration and neutralization 24 in FIG. 1A). The final solution includes the hyperpolarized MR probe for injection into subject 26, which is scanned by MR system 12 in order to detect the MR signal emitted by the nuclei before the MR signal dissipates below a minimum detection level of the MR system 12.

MR applications using hyperpolarized ¹³C MR probes are particularly powerful molecular characterization tools because MR using hyperpolarized ¹³C MR probes permits a safe, real-time or near real-time, non-radioactive, and pathway specific analysis of physiological processes that were previously inaccessible for spectroscopic and imaging applications. Similarly, the occurrence of nitrogen in biological systems makes nitrogen another species of interest for metabolic investigation using Nitrogen 15 (¹⁵N) nuclei MR probes, particularly in N-enriched probes subjected to hyperpolarization. There are, however, several technical challenges of known hyperpolarized MR probe compositions and methods.

In known MR probe compositions and methods, hyperpolarization of ¹³C and/or ¹⁵N NMR probes is adversely affected by the addition of water used to modify glassification agent concentration. For example, pyruvic acid has been demonstrated as a glassification agent during PA-urea co-polarization. Upon the addition of water to pyruvic acid, increased crystallization of the MR probe mixture occurred, resulting in decreased hyperpolarization of the MR probe. Further, in known MR probe compositions and methods, high concentrations of glassification agents, such as glycerol or pyruvic acid, needed for hyperpolarization may be toxic to a subject and/or cause metabolic perturbations in the processes being observed. For example, pyruvic acid concentrations in known MR probe compositions are multiple times higher than endogenous concentrations of pyruvic acid or conjugate base pyruvate in the human body. As another example, while glycerol is non-endogenous to the human body, glycerol is rapidly metabolized in the body and perturbs the metabolic processes being studied by MR. Also, glycerol has a relatively high viscosity and is difficult to reconstitute at dissolution. Additionally, in known MR probe compositions and methods, non-acidic glassification agents such as glycerol are unable to precipitate EPA or enable EPA removal via filtration from the hyperpolarized MR probe solutions. Following dissolution, EPA should be removed, such as to below 5 μM EPA or to below 3 μM EPA, before being injected into a subject. Moreover, in known MR probe compositions and methods, glassification agents are reactive with MR probes to form undesired reaction products in the MR probe mixtures. In addition, known MR probe compositions and methods include glassification agents with impurities that adversely affect glassification of MR probe mixtures. For example, in previous compositions including pyruvic acid as glassification agent with a urea ¹³C MR probe, three impurity compounds were identified as the cross-reaction product of pyruvic acid and urea.

In contrast, in the compositions and methods described herein, LA was surprisingly identified as a co-polarization probe and glassification matrix for ¹³C-¹⁵N MR probes, and was found to be more suitable than other glassification agents, such as pyruvic acid and glycerol, in several respects. First, adding water to MR probe compositions with LA as glassification agent does not cause crystallization and does not adversely affect the hyperpolarization of the MR probe. Further, glass formed using LA yield MR probes having desirable levels of polarization. Also, LA or conjugate base of lactate is endogenous to the human body at higher concentrations than endogenous pyruvic acid concentrations. In the exemplary embodiment, LA concentrations in MR probe compositions are comparable to endogenous LA concentrations, making MR probe compositions with LA safe and non-toxic. For example, a 0.06 mmol/kg dose of lactate did not result in metabolic perturbations as seen with pyruvic acid or pyruvate. Additionally, LA aids in EPA removal as the acidic component needed for filtration of EPA particles from hyperpolarized MR probe mixture dissolution product. EPA removal in the presence of LA is shown to be comparable to EPA removal in the presence of PA. LA-mediated EPA removal achieved acceptable levels below about 5 μM EPA. Moreover, LA is less reactive than PA, and LA contributes less impurities to MR probe compositions than PA. Urea/LA mixtures contain fewer impurities resulting from cross-reaction, and LA impurities do not adversely affect glassification of MR probe mixtures.

No known publications exist on using LA as a glassification agent. Surprisingly, LA MR probe compositions may be diluted with water without causing crystallization during hyperpolarization, and LA is advantageous over known glassification agents. The small amounts of impurities seen in LA were not adverse to glassification when LA was used as a glassification agent.

FIG. 1B is a flow chart of an exemplary method 100 of preparing a hyperpolarized amorphous solid MR probe material. In the exemplary embodiment, method 100 includes preparing 102 a composition including at least one MR probe, an electron paramagnetic agent, and a glassification agent including LA. Method 100 further includes carrying out 104 dynamic nuclear polarization on the composition to obtain the hyperpolarized amorphous solid MR probe material. FIG. 1C provides a method 150 of preparing a hyperpolarized liquid MR probe solution. Method 150 includes preparing 152 a composition including at least one MR probe, an electron paramagnetic agent, and a glassification agent including LA. Method 150 further includes carrying out 154 dynamic nuclear polarization on the composition to obtain a hyperpolarized amorphous solid MR probe material. Method 150 additionally includes liquefying 156 the hyperpolarized amorphous solid MR probe material by dissolution to obtain the hyperpolarized liquid MR probe solution.

Accordingly, compositions and methods described herein overcome the above described problems in known MR probe compositions and methods by utilizing LA as a glassification agent. In the exemplary embodiment, LA is used as a glassification agent and/or co-polarization (e.g., co-hyperpolarization) agent for MR probe compositions and methods. Further details and examples are described below.

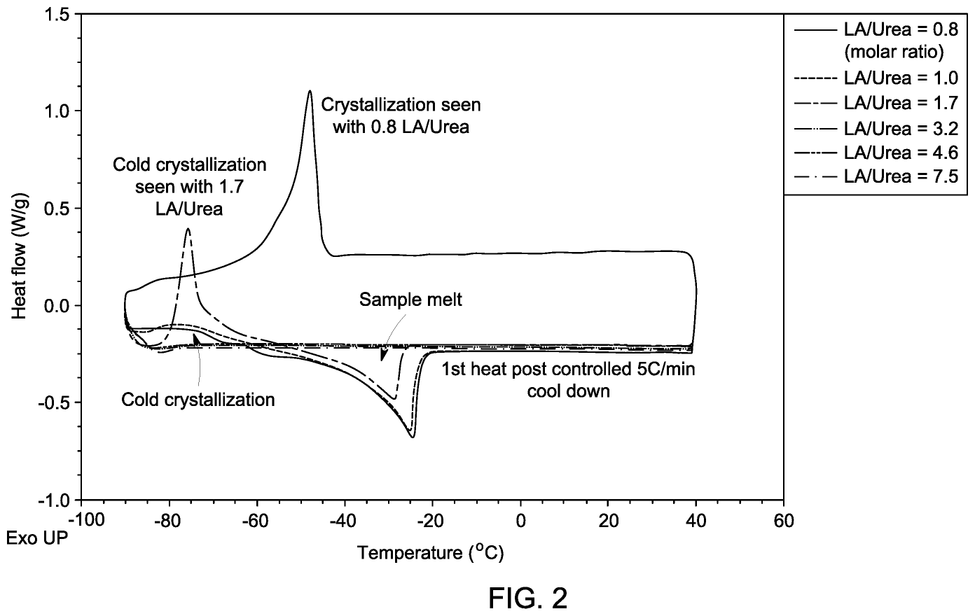

Glassification with LA upon hyperpolarization of ¹³C and/or ¹⁵N MR probes. LA was utilized as a glassification agent for urea MR probe solutions. Based on differential scanning calorimetry (DSC) results described herein, LA/urea mixtures at ˜3.2:1 molar ratio formed a glass. By using LA, the final dissolution product of urea was increased by >30% to 45-67 mM. DSC profiles were run for solutions spanning molar volume ratios of 0.8:1 to 7.5:1 LA:urea. Tests were performed using [1-¹²C] LA and ¹²C urea. Urea in water was first prepared and fully dissolved before mixing with LA. Samples were loaded at room temperature, heated and held isothermally for 30 minutes prior to cooling to below freezing. Solutions were held isothermally for 5 minutes below freezing and then re-heated with a subsequent 30 minute isothermal hold to ensure complete sample melting. The process was repeated for each sample and a constant ramp rate of 5° C./minute was used. Results are shown in FIG. 2 and demonstrate that crystallization-free glassification of the LA:urea mixtures occurs for approximate molar ratios >3, which is similar to findings for pyruvic acid:urea mixtures. In the exemplary embodiment, ¹²C-LA is used solely as glassification agent, e.g., as a glassification excipient, for [¹³C,¹⁵N] urea. Alternatively, ¹²C-LA is used in combination with ¹³C LA, or ¹³C-labeled LA only is used to replace [1-¹³C] pyruvic acid in some hyperpolarized MR probe applications. For example, in cardiac hyperpolarized ¹³C MR studies, [1-¹³C] LA has been shown to be a viable substrate used to image key metabolic pathways of cardiac metabolism. Accordingly, the present disclosure demonstrates LA as a suitable glassification agent and/or co-hyperpolarization agent for use with polarizer systems.

Reduced metabolic perturbation using LA as glassification agent. While a typical glassification agent such as glycerol is useful for reducing ice crystal formation during freezing and storage, glycerol is rapidly metabolized in vivo, may be toxic to the subject, and causes perturbations to the metabolic measurements being studied, such as TCA cycle measurements. LA is an endogenous compound in the human body. Because LA concentrations in MR probe compositions (refer to Table 1) are comparable to LA concentrations in the body, LA does not perturb metabolic reactions being observed. In the exemplary embodiment, MR probe compositions include a glassification agent that includes LA at a concentration up to about 90% volume percent LA based on a total volume of the composition.

Polarization using LA as glassification agent. Polarization with LA was evaluated and small dose LA/urea buildup and dissolution with LA was assessed. [¹³C,¹⁵N] urea in L-[1-¹³C] LA mixtures or [1-¹²C] LA mixtures were polarized at <1 K. 4.2:1 and 3.2:1 LA/urea molar ratio mixtures were prepared by adding urea solution to crystalline LA, see Table 1 below. The LA/urea final mixtures has an estimated density of 1.23-1.3 g/ml depending on LA used and mixture ratio. EPA was added to a final concentration of about 15 mM or less EPA.

TABLE 1
LA/urea mixture preparations and estimated dose concentrations.

| | | | Dose at the end |
|---|---|---|---|
| | | | assuming total |
| | | | dose of 1.5 g |
| | | | and final |
| Urea 10M | | | received 65 ml |
| solution | LA | Molar ratio | (85% recovery) |
| 0.3 ml, 0.37 gram | 1.14 gram | 4.2:1 LA/urea, w/w | 177 mM LA, |
| 0.003 mole | 0.0125 mole | 24% urea in water | 44 mM urea |
| 0.35 ml, 0.42 gram, | 1.05 gram, | 3.2:1 LA/urea, w/w | 163 mM LA, |
| 0.0035 mole | 0.0115 mole | 28% urea in water | 49 mM urea |

Samples were polarized with microwave irradiation at an optimal frequency for urea for several hours, then rapidly dissolved in super-heated, pressurized sterile water and subsequently neutralized using neutralization buffer containing NaOH and Tris buffer. Fluid path was used alone or together with an EPA filter for EPA removal.

The various mixing ratios used in the DSC study along with corresponding testing results are shown in Table 2 and FIG. 2. Glassification of the mixtures occurs <−80° C. and undesirable cold crystallization is observed for mixtures with LA:urea at 0.8:1 and 1.7:1. For mixtures with LA/urea ratios <1.7:1, there is a large cold crystallization peak during DSC cool down indicating that the mixture may likely not form a glass during sample introduction to the polarizer and therefore may not achieve a hyperpolarized state. For molar ratios >3.16:1, the mixture is free of crystallization during both cool down and warm up, similar to glassification for pyruvic acid and pyruvic acid:urea mixtures. The presence of a cold crystallization peak at −80° C. during warm up for the sample with molar ratio of 1.73:1 indicates there may be susceptibility to crystallization. The presence of a cold crystallization peak at −80° C. during warm up for the sample with molar ratio of 1.73:1 indicates the sample may be susceptible to crystallization when the sample is exposed to temperature slightly warmer than glass transition temperature. In typical sample insertion processes for a polarizer with multi-sample capability, the sample is cooled more gradually by lowering it deeper and deeper into the cryogenic region in step wise fashion until the sample is in the sample cup and surrounded by liquid helium. The multi-step lowering process is designed to minimize thermal impact to liquid helium environment in the sample cup (<1 K) where another sample may already be present, and also to avoid excessive liquid helium boil off during the sample insertion process. This multi-step process might subject the sample to a range of temperatures from 250 K to 1 K until the sample is fully equilibrated thermally with the sample space environment. A sample susceptible to crystallization upon slight temperature change is therefore not suitable for hyperpolarization utilizing the typical sample insertion protocol. A fast sample insertion procedure to achieve faster cooling is contemplated herein to address the crystallization issue. In an example protocol, the sample is immediately inserted to a deeper position which is colder than the first few lowering positions in the typical multi-step insertion protocol, then the sample is retracted to a higher position momentarily before being fully lowered into a sample cup with liquid helium. This protocol allows the sample to reach a lower temperature faster, but may warm up the sample cup to >3 K for a period of time up to 30 minutes, and impacting the polarization process of other samples that may already be present in the polarizer. Additionally, a smaller percentage of acid at 1.73:1 molar ratio might also lead to higher residual EPA concentrations. Molar ratios of 4:1 and 3:1 were settled upon in terms of both polarization and EPA removal.

TABLE 2
DSC sample mixtures and observations.

| | | | | volume | molar | | |
|---|---|---|---|---|---|---|---|
| | Urea | LA | Tot | ratio | ratio | | Polarizer |
| Mixes | (mL) | (mL) | (mL) | LA/Urea | (LA/urea) | DSC summary | performance |
| #6 | 1.33 | 8.67 | 10 | 6.5 | 7.48 | No cold | High chance to |
| #4 | 2.00 | 8.00 | 10 | 4 | 4.60 | crystallization, | work with regular |
| #5 | 2.67 | 7.33 | 10 | 2.75 | 3.16 | glass transition | insertion process |
| | | | | | | temperature (Tg) | |
| | | | | | | lower than LA's | |
| | | | | | | Tg | |
| #1 | 4.00 | 6.00 | 10 | 1.5 | 1.73 | Cold crystallization | Might work with |
| | | | | | | upon warming | fast insertion |
| #2 | 5.33 | 4.67 | 10 | 0.875 | 1.01 | Crystallization in | Not likely to form |
| #3 | 6.00 | 4.00 | 10 | 0.67 | 0.77 | cooling down | glass |

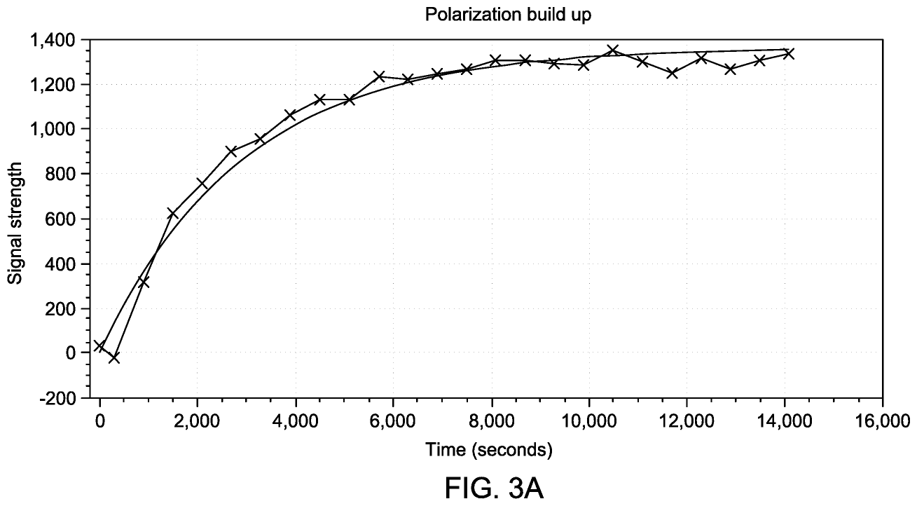

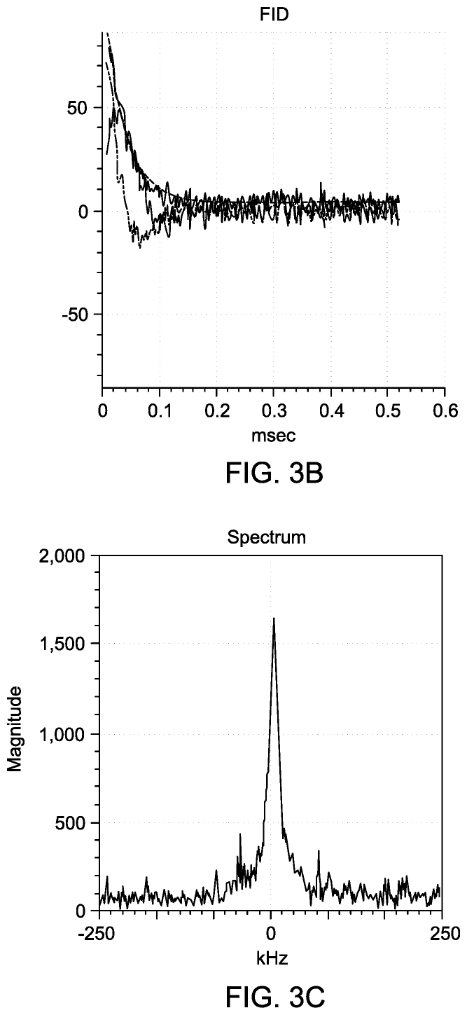

As a further example, a small dose experiment using a 4.2:1 [1-¹³C] LA/[¹³C,¹⁵N] urea mixture with EPA was used to investigate solid phase buildup in a hyperpolarizing system and a dissolution experiment without EPA filtration was further performed. The sample vial was elevated higher than the typical lowered position in order to center the sample within the NMR coil so that solid phase buildup from a small sample may be monitored with a good signal to noise ratio. The optimal microwave frequency for urea was used, which is 0.01 GHz lower than ¹³C-pyruvic acid. A time constant of 2905s was reported, see FIG. 3A-3C, indicating that the 4.2:1 ratio mixture with LA forms a satisfactory glass within the hyperpolarizer, and which was consistent with DSC study results.

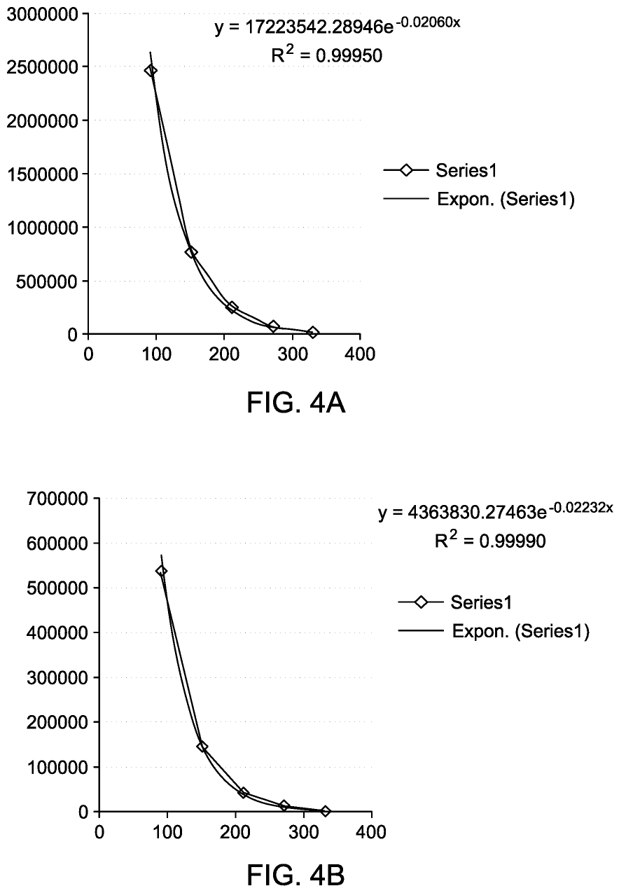

Dissolution medium was loaded into the dissolution syringe. Dissolution after 4 hours of buildup went smoothly and the dissolved LA and urea mixture was received in a bottle containing neutralization medium. Liquid phase polarization (LSP) was estimated. LSP indicates the extent of polarization of nuclei (e.g., ¹³C or ¹⁵N nuclei) in an MR probe, and may be expressed as the percentage of total nuclear spins that have become highly polarized in an MR probe, such that a higher LSP results in a higher MR signal. In the exemplary embodiment for injection into a subject, a hyperpolarized ¹³C MR probe should have an LSP of at least about 20%, where at least about 20% of the total ¹³C nuclei in the MR probe have highly polarized ¹³C nuclear spins. LSP was monitored with the first measurement started at 91 seconds. Additional samples were tested every minute after the first measurement to monitor signal decay. LSP was estimated by comparing the hyperpolarized product spectrum to the thermal-equilibrium spectrum and then back-calculating to the time of dissolution using T1 time constants fit by the measurements, see FIG. 4A-4B. The LSPs at time of dissolution were calculated to be 34% and 36% for LA and urea, respectively. Without hyperpolarization, available MR signals at thermal equilibrium is approximately 2.5 ppm at 3T. A 34% or 36% of LSP indicates an increase of 135,000 or 144,000 times in available MR signals, which is several orders of magnitude of increase.

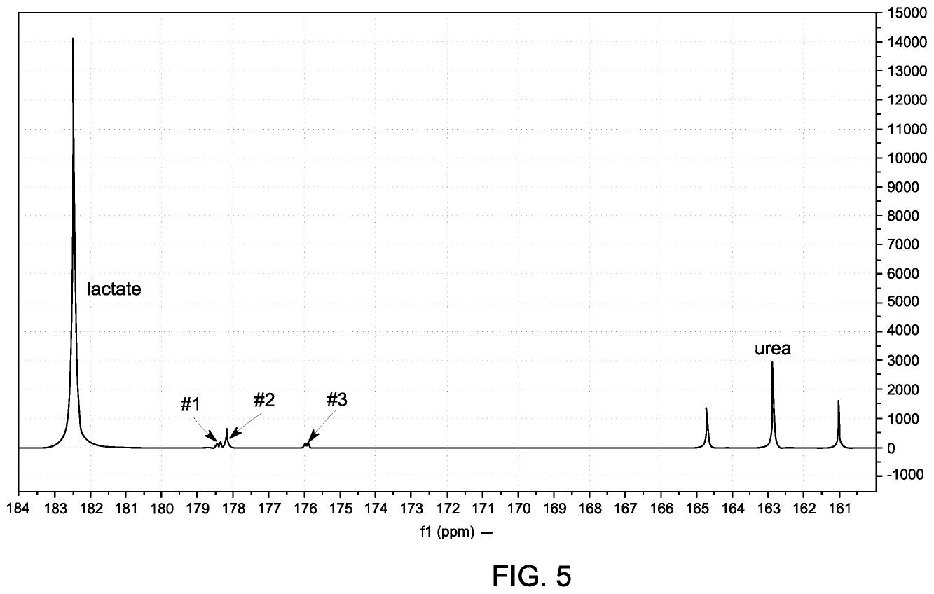

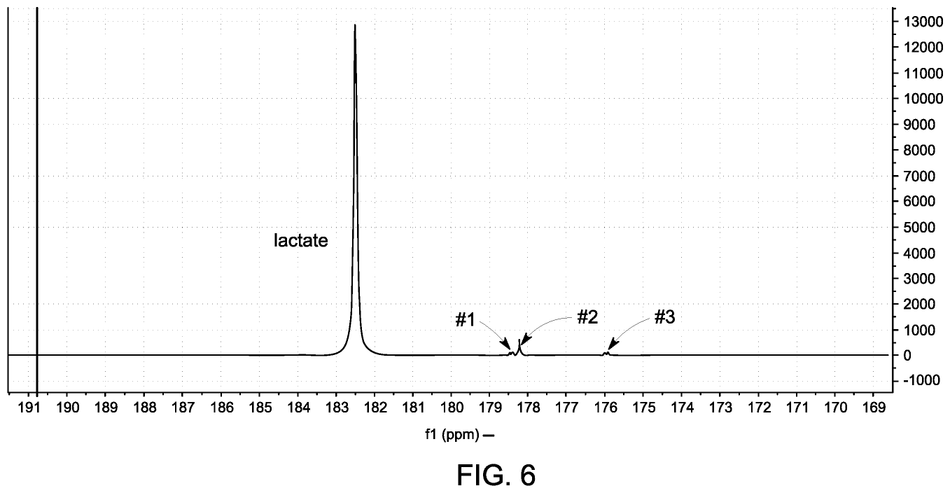

Polarization and dissolution with LA as glassification agent. FIG. 5 shows a first measurement spectrum from a MR probe hyperpolarized sample, which includes peaks from lactate carbonyl, urea carbonyl and a few other low intensity peaks. LA-only dissolution determined that the small peaks observed in FIG. 5 were contaminants/impurities from the LA as opposed to byproducts from a urea+LA reaction, as previous studies have shown no significant urea-associated impurities. A buildup and dissolution run of [1-¹³C] lactate with water and added EPA was also performed. As shown in FIG. 6, low intensity peaks observed in FIG. 5 were also present, confirming the presence of small peaks in LA alone. The doublet feature for #1 and #3 are similar as well. The results in FIGS. 5 and 6 show that LA is not reactive to MR probes. Table 3 shows calculated T1 for lactate, urea, and impurity peaks, and which supports hyperpolarization with LA.

TABLE 3
Estimated T1 in background magnetic field (1-10 Gauss)
by fitting signal decay of 5 consecutive measurements.

| | MR Urea |
|---|---|
| T1 | Probe |
| LA + urea | 45 s |
| study | |
| LA only study | N/A |

EPA removal using LA as glassification agent. EPA removal performance with LA was evaluated. In MR probe compositions including pyruvic acid, EPA forms particles in the presence of pyruvic acid during dissolution which then are filtered out using pharmacy kit filters. The residual EPA concentration in the dissolution product is typically less than 3 μM. Clinical site acceptance criteria ranges from about ≤5 μM to about ≤3 μM for EPA concentration in the final injectable solution. During co-polarization of pyruvic acid-urea protocol, starting EPA concentration was below mM and final EPA concentrations below about 3 μM were reported.

While LA has a higher pKa value (3.8) than pyruvic acid (2.45), the acidic condition imparted by LA was shown to be suitable in forming EPA particles for removal via filtration. Previous work has shown that fumaric acid with pKa>3.0 (e.g., pKa=3.03, 4.44) resulted in residual EPA at a few μMs higher than the typical concentration from pyruvic acid dissolution. In dissolution runs described herein with 4.2:1 and 3.2:1 LA/urea ratio, ¹²C LA was used instead of the high cost ¹³C version.

Table 4 shows formula and dissolution results with [¹³C,¹⁵N] urea prepared in ¹²C LA. A concentration of 12 mM EPA was used in the starting mixture, similar to concentrations typically used for the study of pyruvic acid/urea mixtures. For 12 mM EPA concentration, the solid phase polarization built up slower but reach a higher level. The residual EPA concentration from 3.2:1 ratio mixture is higher than 4.2:1 mixture since less LA is present. Therefore, according to the acceptance criteria for human subject injection of ≤5 μM EPA, the LA formulations of the present disclosure are acceptable. The 3.2:1 ratio provided 141 mM lactate and 42 mM urea at 80% recovery. Exemplary embodiments of the present disclosure utilizing LA co-polarization may provide 20-40% higher concentration of urea relative to the above-described example of 35 mM [¹³C,¹⁵N] urea from pyruvic acid co-polarization.

TABLE 4
Summary of dissolution runs for EPA removal evaluation.

| | ~4.2:1 LA/urea run | ~3.2:1 LA/urea run |
|---|---|---|
| Dissolution medium (g) | 41.5178 | 42.6264 |
| Dose weight (g) | 1.4458 | 1.4551 |
| Final product mass (g) | 63.9817 | 62.675 |
| Dead volume (g) | 15.0724 | 15.6048 |
| Recovery estimate | 82% | 82% |
| EPA concentration | 2 μM | 3 μM |
| Liquid phase | 31% | 42% |
| polarization | | |
| ¹²C-lactate | 153 mM | 141 mM |
| concentration* | | |
| ¹³C,¹⁵N-urea | 37 mM | 42 mM |
| concentration** | | |

*¹²C-lactate is measured by absorbance at 235 nm. Calibration is corrected for EPA contribution. The concentration is consistent with pH based recovery estimate.
**Urea concentrations listed here are based on LA/urea ratio of starting dose.

In the exemplary embodiment, the use of LA either as a ¹²C glassification agent in a [¹³C—¹⁵N] urea solution and/or as a ¹³C co-hyperpolarization probe warrants quality control checks to ensure non-harmful LA and EPA concentrations prior to subject injection. As another example, LA absorbance may be suitably monitored provided that a UV-transparent cuvette (e.g., quartz) is used. Maximum absorption by LA occurs in the ultra-violet range (<230 nm), which is below the transmission range for disposable methacrylic or polysterene cuvettes as in previously used compositions and methods to measure pyruvic acid.

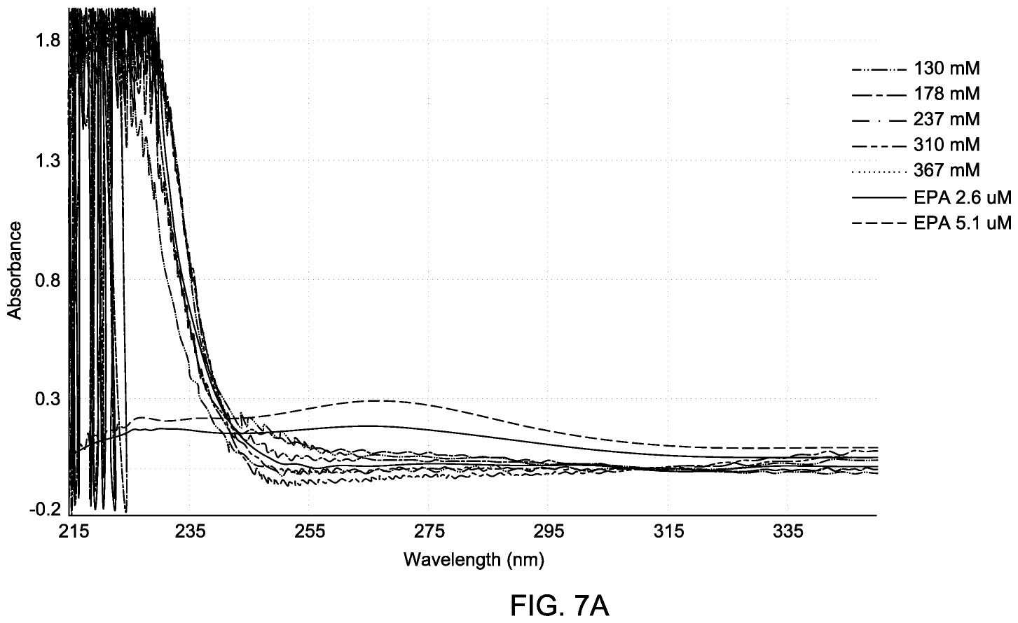

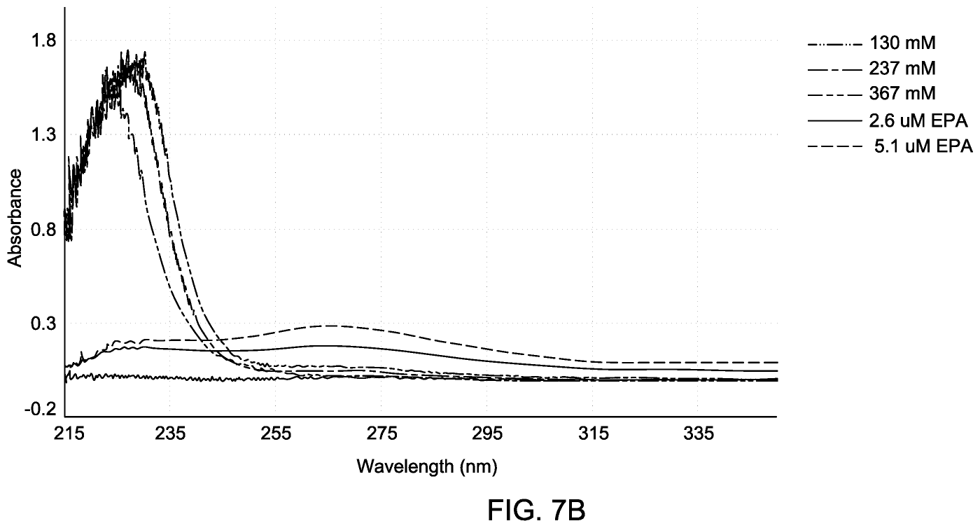

Preliminary absorbance measurements of LA were carried out using 1-cm quartz cuvettes (non-disposable). Additional spectra were obtained using disposable cuvettes and results for both tests are shown in FIG. 7A and FIG. 7B, and in Table 5. Absorbance measurements were taken at 235±1 nm, on low-energy the tail of the LA peak—similar to absorbance measurement procedures used for pyruvic acid. FIG. 7A and FIG. 7B further show two solutions containing EPA at relatively high concentrations superimposed on the lactate spectra, indicating that quantification of lactate should take into account EPA concentration.

TABLE 5
Average absorbance intensity values for 5 lactate
solutions through quartz and disposable cuvettes.

| | Quartz | | disposable | |
|---|---|---|---|---|
| Lactate | Abs | | cuvette Abs | |
| mM | 235 | 1 sd | 235 | 1 sd |
| 130 | 0.493 | 0.065 | 0.489 | 0.002 |
| 178 | 0.644 | 0.059 | | |
| 237 | 0.772 | 0.016 | 0.782 | 0.009 |
| 310 | 0.891 | 0.024 | | |
| 367 | 1.108 | 0.018 | 1.065 | 0.004 |

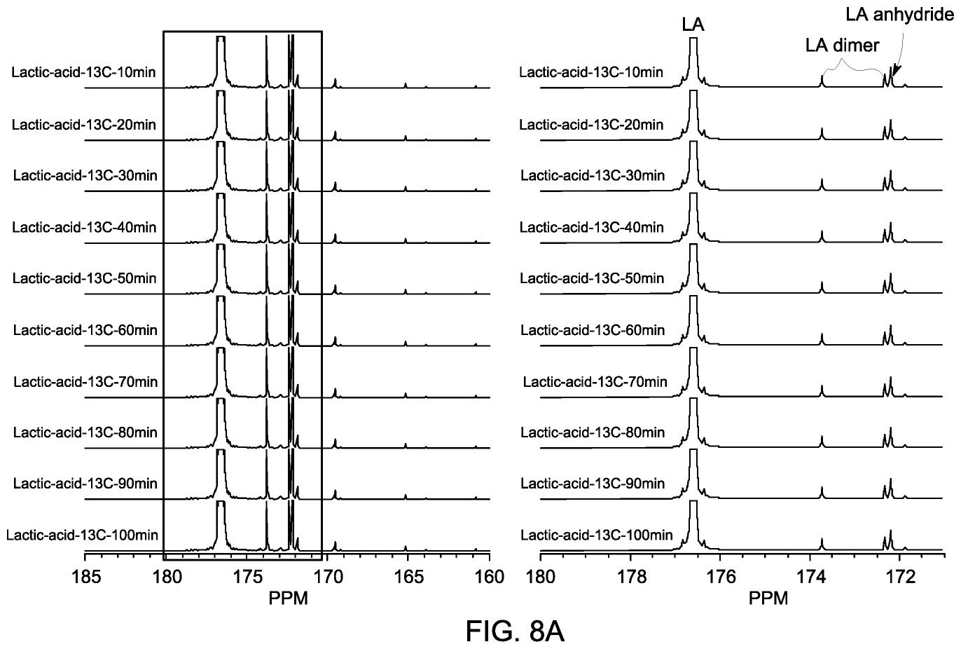

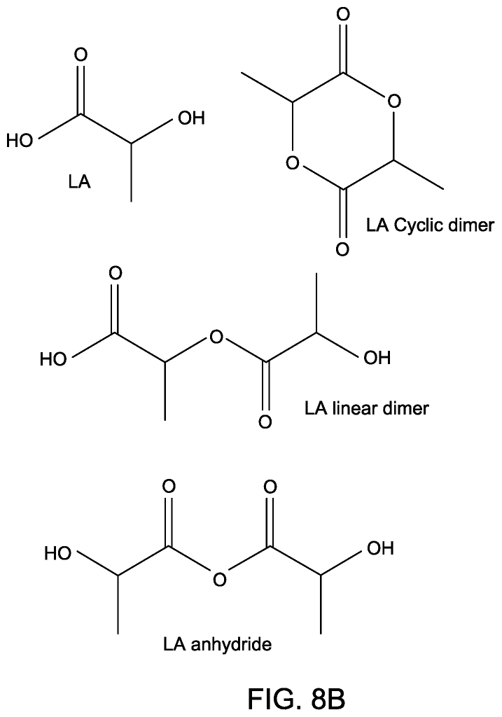

LA-associated impurities and LA-associated side reaction products. NMR studies of ¹³C LA with or without urea in water were performed to evaluate the contribution of LA-associated impurities side reaction products with MR probes. Potential contaminants within the LA and potential reaction products (e.g., between LA+urea, LA+EPA, LA+neutralization buffer(s)), were identified. Identified contaminants and/or reaction products were examined via time-series. Starting materials included ¹³C LA and ¹³C-¹⁵N Urea, results spectra are shown in FIGS. 8-14.

FIG. 8A shows exemplary ¹³C NMR spectra of LA in D₂O. The peaks from 172 to 174 ppm appeared to be LA linear dimer and LA anhydride, see FIG. 8B. Concentrations did not change significantly over the first 1.5 hrs.

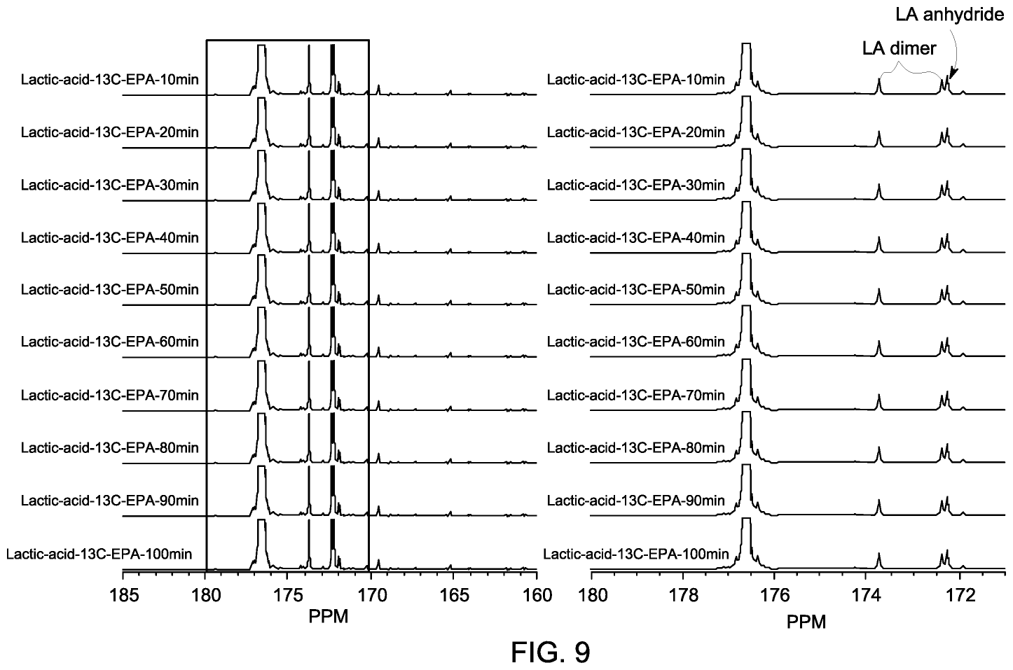

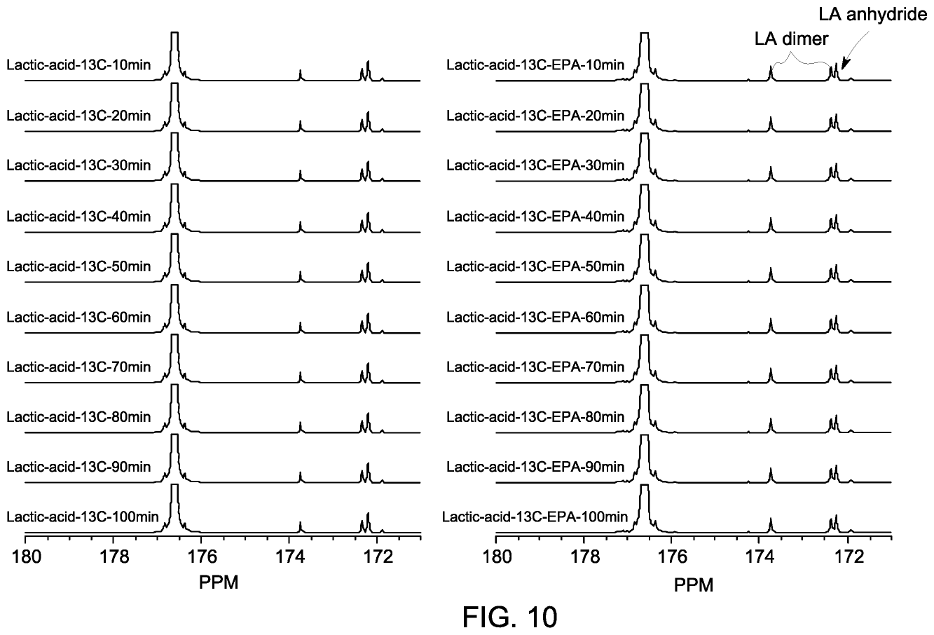

FIG. 9 shows exemplary ¹³C NMR spectra of LA in water with EPA added in D₂O. The same peaks were detected as in the samples without EPA as shown in FIG. 8A. The samples with and without EPA are compared in FIG. 10 and Table 6, below.

FIG. 10 shows an exemplary comparison of ¹³C NMR spectra for LA in water with EPA versus without EPA. The amount of LA linear dimer relative to total LA increased slightly with time and adding EPA, while that of the anhydride slightly decreased as shown in Table 6.

TABLE 6
Molar percentages of LA dimer and LA anhydride in
¹³C-LA both without and with concentrated EPA.

| | |
|---|---|
| Mole % linear | Mole % |
| dimer | anhydride |

¹³C-LA

| | | |
|---|---|---|
| Lactic-acid-13C-10 min. | 0.9% | 0.7% |
| Lactic-acid-13C-20 min. | 0.9% | 0.7% |
| Lactic-acid-13C-30 min. | 0.9% | 0.7% |
| Lactic-acid-13C-40 min. | 0.9% | 0.7% |
| Lactic-acid-13C-50 min. | 0.9% | 0.7% |
| Lactic-acid-13C-60 min. | 0.9% | 0.7% |
| Lactic-acid-13C-70 min. | 0.9% | 0.7% |
| Lactic-acid-13C-80 min. | 0.9% | 0.7% |
| Lactic-acid-13C-90 min. | 0.9% | 0.7% |
| Lactic-acid-13C-100 min. | 0.9% | 0.7% |

¹³C-LA-concentrated-EPA

| | | |
|---|---|---|
| Lactic-acid-13C-EPA-10 min. | 1.0% | 0.6% |
| Lactic-acid-13C-EPA-20 min. | 1.0% | 0.6% |
| Lactic-acid-13C-EPA-30 min. | 1.0% | 0.6% |
| Lactic-acid-13C-EPA-40 min. | 1.0% | 0.6% |
| Lactic-acid-13C-EPA-50 min. | 1.0% | 0.6% |
| Lactic-acid-13C-EPA-60 min. | 1.0% | 0.6% |
| Lactic-acid-13C-EPA-70 min. | 1.1% | 0.6% |
| Lactic-acid-13C-EPA-80 min. | 1.1% | 0.6% |
| Lactic-acid-13C-EPA-90 min. | 1.1% | 0.6% |
| Lactic-acid-13C-EPA-100 min. | 1.1% | 0.6% |

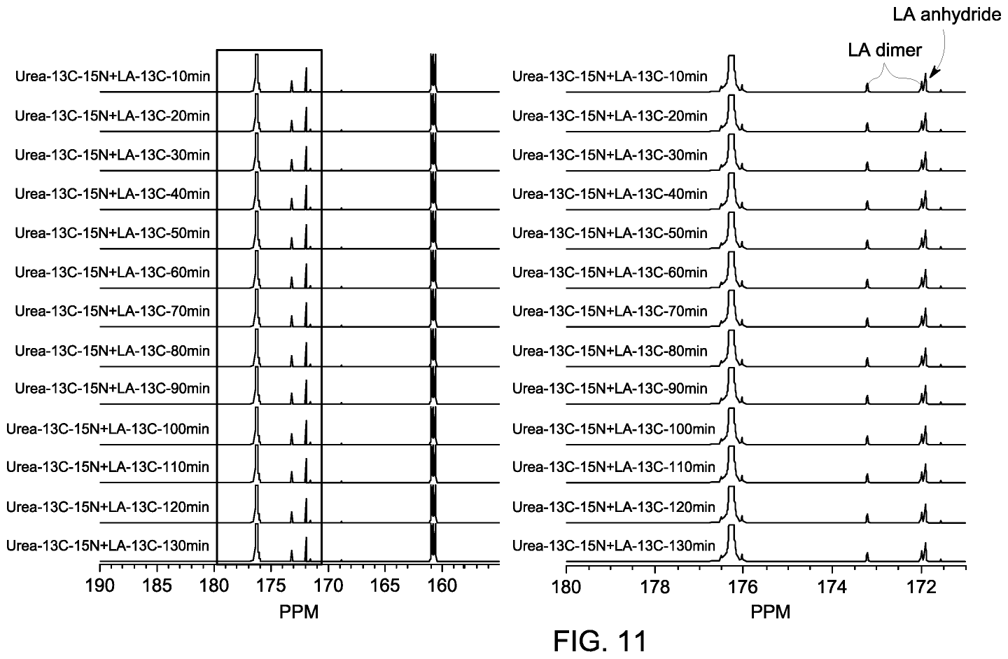

FIG. 11 shows exemplary ¹³C NMR spectra of LA and urea mixtures in D₂O. The peaks from 171.5 to 173.5 ppm were the same set of LA linear dimer and LA anhydride peaks as detected in the LA only samples. Concentrations did not change significantly over the first 2 hrs.

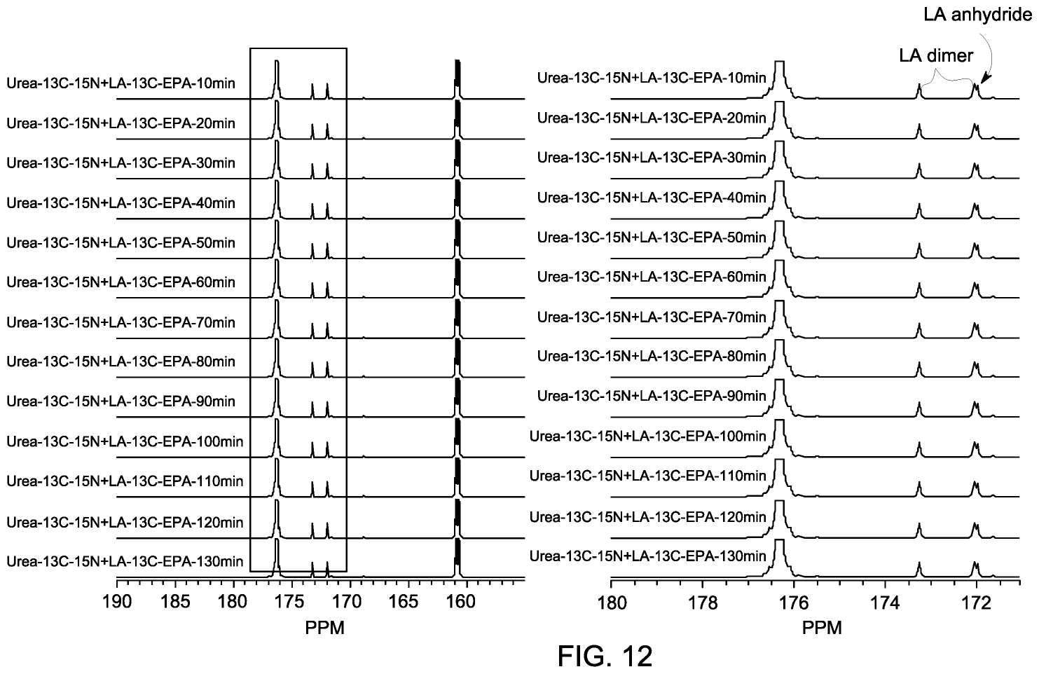

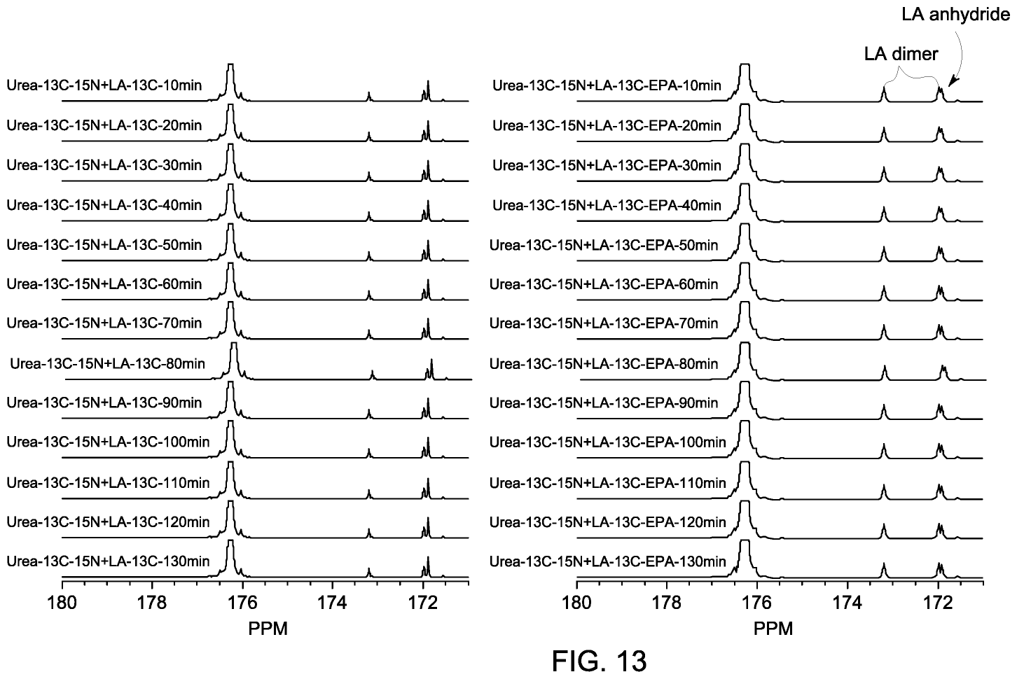

FIG. 12 shows exemplary ¹³C NMR spectra of LA and urea mixtures with EPA added in D₂O. The same peaks were detected as in the samples without EPA, as shown in FIG. 11. Samples with and without EPA are compared in FIG. 13 and Table 7 below.

FIG. 13 shows an exemplary comparison ¹³C NMR spectra of LA and urea mixtures with EPA versus without EPA. The amount of LA linear dimer relative to total LA increased slightly with time and adding EPA, while that of the anhydride decreased as shown in Table 7.

TABLE 7
Molar percentages of LA dimer and LA anhydride in ¹³C-
urea-¹³C-¹⁵N + LA mixtures, both without and with EPA.

| | |
|---|---|
| Mole % linear | Mole % |
| dimer | anhydride |

¹³C-Urea-¹³C-¹⁵N + LA mixture

| | | |
|---|---|---|
| Urea-13C-15N + LA-13C-10 min. | 0.9% | 0.8% |
| Urea-13C-15N + LA-13C-20 min. | 1.0% | 0.8% |
| Urea-13C-15N + LA-13C-30 min. | 1.0% | 0.8% |
| Urea-13C-15N + LA-13C-40 min. | 1.0% | 0.8% |
| Urea-13C-15N + LA-13C-50 min. | 1.0% | 0.8% |
| Urea-13C-15N + LA-13C-60 min. | 1.0% | 0.8% |
| Urea-13C-15N + LA-13C-70 min. | 1.0% | 0.8% |
| Urea-13C-15N + LA-13C-80 min. | 1.0% | 0.8% |
| Urea-13C-15N + LA-13C-90 min. | 1.0% | 0.8% |
| Urea-13C-15N + LA-13C-100 min. | 1.0% | 0.8% |
| Urea-13C-15N + LA-13C-110 min. | 1.0% | 0.8% |
| Urea-13C-15N + LA-13C-120 min. | 1.0% | 0.8% |
| Urea-13C-15N + LA-13C-130 min. | 1.0% | 0.8% |

¹³C-Urea-¹³C-¹⁵N + LA mixture-EPA

| | | |
|---|---|---|
| Urea-13C-15N + LA-13C-EPA-10 min. | 1.3% | 0.5% |
| Urea-13C-15N + LA-13C-EPA-20 min. | 1.3% | 0.6% |
| Urea-13C-15N + LA-13C-EPA-30 min. | 1.3% | 0.6% |
| Urea-13C-15N + LA-13C-EPA-40 min. | 1.3% | 0.5% |
| Urea-13C-15N + LA-13C-EPA-50 min. | 1.3% | 0.5% |
| Urea-13C-15N + LA-13C-EPA-60 min. | 1.3% | 0.6% |
| Urea-13C-15N + LA-13C-EPA-70 min. | 1.3% | 0.5% |
| Urea-13C-15N + LA-13C-EPA-80 min. | 1.3% | 0.5% |
| Urea-13C-15N + LA-13C-EPA-90 min. | 1.3% | 0.6% |
| Urea-13C-15N + LA-13C-EPA-100 min. | 1.3% | 0.5% |
| Urea-13C-15N + LA-13C-EPA-110 min. | 1.3% | 0.5% |
| Urea-13C-15N + LA-13C-EPA-120 min. | 1.3% | 0.5% |
| Urea-13C-15N + LA-13C-EPA-130 min. | 1.3% | 0.5% |

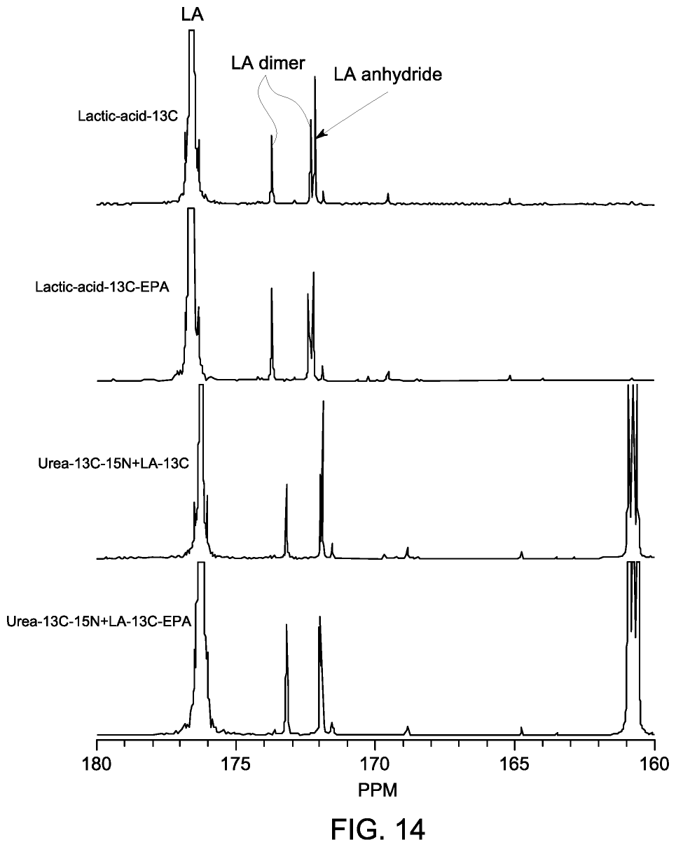

FIG. 14 shows an exemplary comparison ¹³C NMR spectra of LA in water with or without EPA versus LA and urea mixture with or without EPA. Spectra are shown beginning about 10 min after dissolution of LA, or mixing with urea. While a slight shift in peak positions was observed, no new species appear to have formed with addition of urea and EPA. The amount of LA linear dimer relative to total LA slightly increased with time and adding EPA, while that of the anhydride decreased. Chemical shift of the anhydride may agree with a cyclic dimer of LA, however, the instability of the anhydride species in water resulted in assignment as LA anhydride. The cyclic dimer was not further reactive.

Accordingly and based on the above, one or more technical effects of the compositions and methods described herein include: (a) glassification with LA during hyperpolarization of ¹³C and/or ¹⁵N MR probes, (b) EPA removal via filtration in the presence of LA, (c) non-toxic MR probe mixtures with LA, (d) hyperpolarization of MR probe mixtures with LA not being adversely affected by addition of water, (e) improved MR analysis due to decreased metabolic perturbations with LA, (f) reduced impurity contributions by LA, and (g) reduced undesired reaction products in MR probe mixtures with LA.

Definitions and methods described herein are provided to better define the present disclosure and to guide those of ordinary skill in the art in the practice of the present disclosure. Unless otherwise noted, terms are to be understood according to conventional usage by those of ordinary skill in the relevant art.

In the exemplary embodiment, numbers expressing quantities of ingredients, properties such as molecular weight, reaction conditions, and so forth, that may be used to describe and claim aspects of the present disclosure are to be understood as being modified in some instances by the term “about.” The term “about” is used to indicate that a value includes the standard deviation of the mean for the device or method being employed to determine the value. The numerical parameters set forth in the written description and attached claims are approximations that vary depending upon the desired properties sought to be obtained by a particular aspect of the disclosure. The numerical parameters are be construed in light of the number of reported significant digits and by applying ordinary rounding techniques. Notwithstanding that the numerical ranges and parameters setting forth the broad scope of aspects of the present disclosure are approximations, the numerical values set forth in the specific examples are reported as precisely as practicable. The numerical values presented in aspects of the present disclosure may contain certain errors necessarily resulting from the standard deviation found in respective testing measurements. The recitation of ranges of values herein is merely intended to serve as a shorthand method of referring individually to each separate value falling within the range. Unless otherwise indicated herein, each individual value is incorporated into the specification as if it were individually recited herein.

The terms “a” and “an” and “the” and similar references used in the context of describing a particular aspect (especially in the context of certain of the following claims) may be construed to cover both the singular and the plural, unless specifically noted otherwise. The term “or” as used herein, including the claims, may be used to mean “and/or” unless explicitly indicated to refer to alternatives only or to refer to the alternatives that are mutually exclusive.

The terms “comprise,” “have” and “include” are open-ended linking verbs. Any forms or tenses of one or more of these verbs, such as “comprises,” “comprising,” “has,” “having,” “includes” and “including,” are also open-ended. For example, any method that “comprises,” “has” or “includes” one or more steps is not limited to possessing only those one or more steps and may also cover other unlisted steps. Similarly, any composition or device that “comprises,” “has” or “includes” one or more features is not limited to possessing only those one or more features and may cover other unlisted features.

All methods described herein are performed in any suitable order unless otherwise indicated herein or otherwise clearly contradicted by context. The use of any and all examples, or exemplary language (e.g. “such as”) provided with respect to exemplary embodiments described herein is intended merely to better illuminate the present disclosure and does not pose a limitation on the scope of the present disclosure otherwise claimed. No language in the specification should be construed as indicating any non-claimed element essential to the practice of the present disclosure.

Groupings of alternative elements or aspects of the present disclosure disclosed herein are not to be construed as limitations. Each group member is referred to and claimed individually or in any combination with other members of the group or other elements found herein. One or more members of a group are included in, or deleted from, a group for reasons of convenience or patentability. When any such inclusion or deletion occurs, the specification is herein deemed to contain the group as modified thus fulfilling the written description of all Markush groups used in the appended claims.

To facilitate the understanding of the aspects described herein, a number of terms are defined below. The terms defined herein have meanings as commonly understood by a person of ordinary skill in the areas relevant to the present disclosure. Terms such as “a,” “an,” and “the” are not intended to refer to only a singular entity, but rather include the general class of which a specific example may be used for illustration. The terminology herein is used to describe specific aspects of the disclosure, but terminology usage does not delimit the disclosure, except as outlined in the claims.

All of the compositions and/or methods disclosed and claimed herein may be made and/or executed without undue experimentation in light of the present disclosure. While the compositions and methods of this disclosure have been described in terms of the aspects included herein, it will be apparent to those of ordinary skill in the art that variations may be applied to the compositions and/or methods and in the steps or in the sequence of steps of the method described herein without departing from the concept, spirit, and scope of the disclosure. All such similar substitutes and modifications apparent to those skilled in the art are deemed to be within the spirit, scope, and concept of the disclosure as defined by the appended claims.

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A composition comprising:
a magnetic resonance (MR) probe; and
a glassification agent comprising lactic acid.

2. The composition of claim 1, wherein the MR probe includes at least one of a ¹³C MR probe or a ¹⁵N MR probe.

3. The composition of claim 1, wherein the MR probe is a hyperpolarized ¹³C MR probe.

4. The composition of claim 1, wherein the lactic acid and the MR probe has a molar ratio equal to or greater than 2:1.

5. The composition of claim 1, wherein the MR probe includes lactic acid.

6. The composition of claim 1, wherein the MR probe is a carbonyl compound.

7. The composition of claim 7, wherein the carbonyl compound comprises a carboxylic acid.

8. The composition of claim 7, wherein the carbonyl compound comprises urea.

9. The composition of claim 1, wherein the MR probe is a non-carbonyl compound.

10. A method of preparing a hyperpolarized magnetic resonance (MR) probe material, the method comprising:
preparing a composition, the composition including:
an MR probe;
an electron paramagnetic agent (EPA); and
a glassification agent comprising lactic acid; and
obtaining a hyperpolarized amorphous solid MR probe material by carrying out polarization on the composition.

11. The method of claim 10, wherein the lactic acid and the MR probe has a molar ratio equal to or greater than 2:1.

12. The method of claim 10, wherein preparing the composition further comprises mixing the MR probe with the glassification agent via a fast insertion procedure.

13. The method of claim 10, wherein the MR probe includes at least one of a ¹³C MR probe or a ¹⁵N MR probe.

14. The method of claim 10, wherein the MR probe includes lactic acid.

15. A method of preparing a hyperpolarized magnetic resonance (MR) probe, the method comprising:
preparing a composition comprising an MR probe, an electron paramagnetic agent (EPA), and a glassification agent comprising lactic acid;
carrying out polarization on the composition to obtain a hyperpolarized amorphous solid MR probe material; and
liquefying the hyperpolarized amorphous solid MR probe material by dissolving the hyperpolarized amorphous solid MR probe material to obtain a hyperpolarized liquid MR probe solution.

16. The method of claim 15, further comprising:
filtering the EPA from the hyperpolarized liquid MR probe solution.

17. The method of claim 16, wherein filtering the EPA further comprises filtering the EPA from the hyperpolarized liquid MR probe solution with aid of an acid.

18. The method of claim 17, wherein filtering the EPA further comprises filtering the EPA from the hyperpolarized liquid MR probe solution with aid of the lactic acid.

19. The method of claim 15, wherein the MR probe includes at least one of a ¹³C MR probe or a ¹⁵N MR probe.

20. The method of claim 15, wherein the MR probe includes lactic acid.
